(19) United States
(12) Patent Application Publication
(10) Pub. No.: US 2011/0002094 A1
(43) Pub. Date: Jan. 6, 2011

(54) INTELLIGENT PERSONAL CARRIER

(76) Inventor: Frédéric Blouin, Quebec (CA)

Correspondence Address: Franz BONSANG;c/o EQUINOX PROTECTION, 410 - 1500, Du College, St-Laurent, QC, H4L 5G6, CA

(21) Appl. No.: 12/735,884

(22) PCT Filed: Feb. 25, 2008
(86) PCT No.: PCT/CA2008/000337

§ 371 Date: Aug. 24, 2010

(51) Int. Cl. H05K 7/00

(52) U.S. Cl. 361/679.01

(57) ABSTRACT

The intelligent personal carrier (IPC) provides a carrier (10) for personal items such as money, credit cards, driver's licenses and other articles and allows electronic devices (22) such as the mobile phone, MP3 player, PDA, camera, health monitors and other devices to be attached to the exterior, leaving them accessible for operation. The IPC may be attached to a strap (40) to attach to the user, such as a lanyard. The strap (40), itself a personal carrier, may have integrated electronics (42, 46, 48, 52) allowing for the control and operation of the attached electronic device. The IPC stores, protects, communicates, detects and tracks personal information and assets. The type of information and personal items to be managed may be in both hard form, such as credit cards, and identification cards, and digitally, in the form of data files.

### FIELD OF THE INVENTION

The present invention relates to carriers for personal articles and devices, and more specifically to an intelligent personal carrier that stores personal articles such as credit cards and dollar bills and also incorporates integrates the most important devices carried on a person into one central carrying system to be worn on the body.

### BACKGROUND OF THE INVENTION

The wallets, the cellular phones (or GSM phones—Global System for Mobile Communications), the MP3s (MPEG1 Audio Layer 3—Moving Picture Experts Group), and the PDAs (Personal Digital Assistants) are the most important devices carried around by a person today. These devices have increased personal enjoyment and the ease of communication with other people. Cellular phones allow persons to communicate with others regardless of location, as long as the cell phone receives an adequately strong signal. Other devices, such as MP3 players or the like, are small, lightweight and able to hold large amounts of data, such as thousands of songs. Other devices, such as PDAs, allow people to receive e-mail, log onto the Internet, and do a host of other activities with a wireless connection adding to the free flow of Information. Yet the means to carry and interact with these devices remain rudimentary and fragmented, especially when moving about, thus reducing their efficiency and friendliness for the user. Organizing and carrying these devices often proves to be troublesome and it is desirable to have a system for organizing all the items a person must carry.

Accordingly, there is a need for a central carrying system worn on the body that simplifies the wear of the various devices carried on a person (i.e. the cell phone, mp3, and wallet), increases their overall functionality and produces a new level of hands free experience.

### SUMMARY OF THE INVENTION

It is therefore a general object of the invention to provide a personal carrier that stores personal articles such as credit cards and dollar bills and also and also incorporates integrates the most important devices carried on a person into one central carrying system to be worn on the body.

The intelligent personal carrier (IPC) advantageously provides a carrier for personal items such as money, credit cards, driver's license and other articles and allows electronic devices such as the mobile phone, MP3 player, PDA, camera, health monitors and other devices to be attached to the exterior, leaving them accessible for operation. The IPC may be attached to a strap to attach to the user, such as a lanyard or the like. The strap may have integrated electronics allowing for the control and operation of the attached electronic device. The IPC stores, protects, communicates, detects and tracks personal information and assets. The type of information and personal items to be managed may be in both hard form, such as credit cards, and identification cards, and digitally, in the form of data files.

An advantage of the present invention is to provide a personal organizer that serves the functions of a wallet and provides organization for electronic devices.

Another advantage of the present invention is to provide a personal carrier for personal items and contains a module allowing electronic financial transactions.

Yet another advantage of the present invention is to provide a lightweight, durable case for holding personal effects and carrying electronic devices while still allowing their operation.

Still another advantage of the present invention is to provide a carrying strap made of textiles incorporating electronic components or devices operating with the carrying case.

According to a first aspect of the present invention, there is provided a personal carrier, comprising: a front half having a front panel, a front bottom section and two front side walls; a back half having a back panel, a top wall, a back bottom section and two back side walls; a hinge connected to the bottom section of the front half and the bottom section of the back half allowing the front and back halves to move relative to one another, and at least one fastener located on the back half for releasably connecting an electronic device to the carrier.

In a second aspect of the present invention, there is provided a personal carrier comprising: a carrying strap including a connector for connecting to either a personal carrying case or a personal electronic device; and controls integrated into the strap and connecting to the connector.

Other objects and advantages of the present invention will become apparent from a careful reading of the detailed description provided herein, with appropriate reference to the accompanying drawings.

### BRIEF DESCRIPTION OF THE DRAWINGS

Further aspects and advantages of the present invention will become better understood with reference to the description in association with the following Figures, in which similar references used in different Figures denote similar components, wherein:

FIG. 1 is a front view of a carrying case of a personal carrier in accordance with an embodiment of the present invention;

FIG. 2 is a back view of the carrying case;

FIG. 3 is a side view of the carrying case;

FIG. 4 is a front view of an attachment plate attachable to the carrying case for holding an electronic device;

FIG. 5 is across sectional view of the carrying case with attached electronic device;

FIG. 5a is a top view of the carrying case;

FIG. 6 shows an exploded perspective view of the carrying case;

FIG. 7 is a side view of the carrying case in a first open position;

FIG. 8 is a side view of the carrying case in a second open position;

FIG. 9 is a front view of a body attachment strap of the personal carrier;

FIG. 10 is a rear view of the body attachment strap of FIG. 9;

FIG. 11 is a front view of another embodiment of a body attachment strap in accordance with the present invention; and

FIG. 12 is a front view of the carrying strap of FIG. 11, folded and integrated into a corresponding carrying jacket.

### DETAILED DESCRIPTION OF THE PREFERRED EMBODIMENTS

With reference to the annexed drawings the preferred embodiments of the present invention will be herein described for indicative purpose and by no means as of limitation.

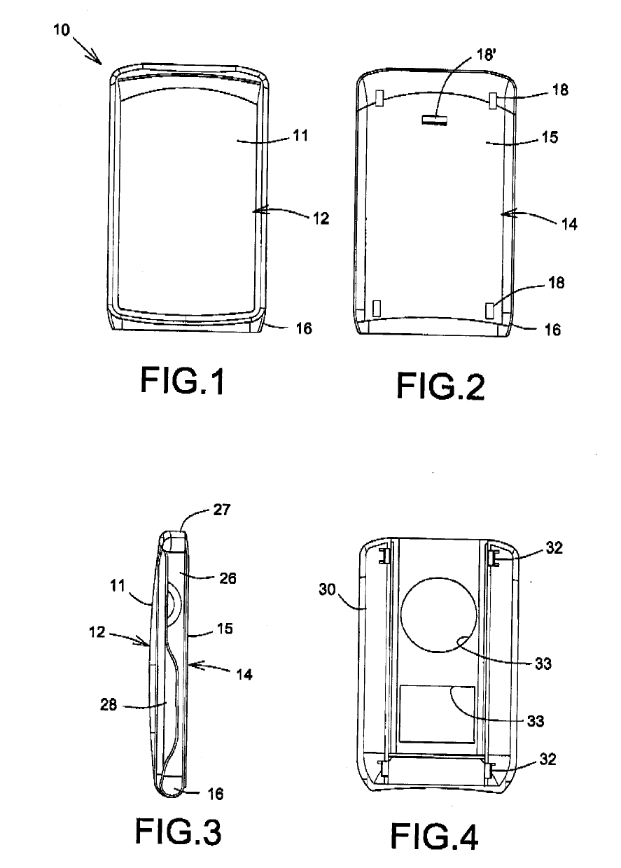

An embodiment of the carrying case 10 of the personal carrier of the present invention, seen in FIGS. 1-3, has a substantially clam shell construction with a rigid front half 12 having a front panel 11 with a bottom section thereof connected to a bottom section of a back half 14 by a hinge 16. The top of the casing 27 extends from a rear, or back, panel 16. A typically female connector 43 is formed in the top, as will be explained later. By having the connector attached to the top which is formed as part of the back half, the connector maintains stability while the case is opened and closed and the connector 43 is attached to a mating connector 42. A rear sidewall 26 extends from the rear panel 15 whereas a front sidewall 28 extends from the front panel 11. A gasket (not shown) may be between the two halves to render the carrying case waterproof.

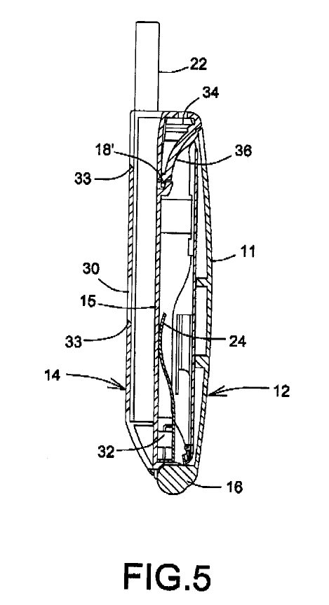

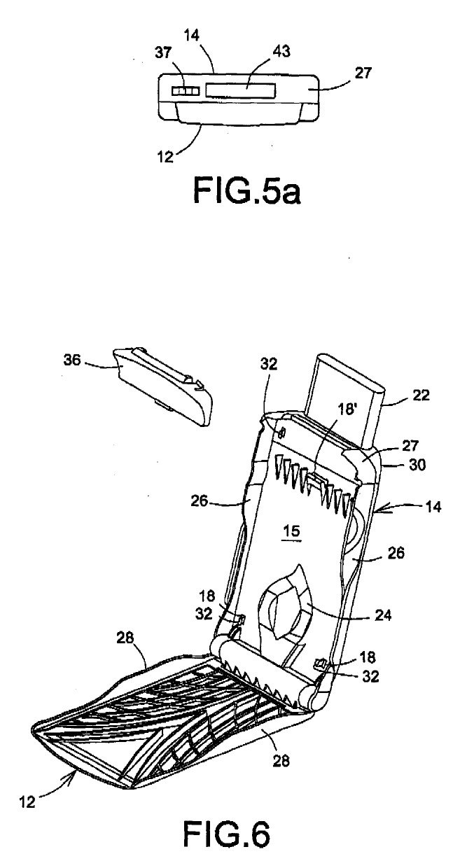

The back panel 16 of the carrying case 10 has at least one mechanical fastener 18, 18′, in the form of openings, hooks or the like, for the releasable connection of either an attachment plate 30 that receives an electronic device 22 (see FIGS. 5 and 5a), such as an MP3 player, a mobile phone, PDA, camera, health monitors and the like other devices, thereon, or the electronic device itself. The attachment plate 30 for an electronic device 22, such as that seen in FIG. 4, has at least one mechanical fastener 32 for mating, such as clipping on, with the panel fastener 18. The attachment plate 30 securely cradles the electronic device and has apertures 33, appropriate for the specific device, to allow access to the controls while the attachment plate is connected to the device. Any conventional manner of connecting the attachment plate to the carrying case may be used, such as mating tracks as used in mobile phones. Other devices which may attach to the exterior of the case include data chips, compass, altimeter, time piece, key holder, cardholder, coin holder, paper money holder and personal protection device or the like, such as pepper spray or the like.

The interior is seen in the cross sectional view of FIG. 5. The interior of either panels 11, 15 is typically provided with a clip 24, or any other types of holders, to secure cards, such as credit cards and a driver's license or the like, as well as paper money. Electronic components can also be incorporated into the interior of the case. The interior typically includes a chamber 34 preferably locked by a panel 36, typically connected to a fastener 18′, which may house an electronic lock, various tracking devices, such as GPS (Global Positioning System), RFID (Radio Frequency Identification) or the like other similar devices, as well as the connector 43. The electronic lock may be activated by a key pad 37, seen in FIG. 5a, or a biometric reader (not shown), on the top of the carrying case 10 or may be remotely actuated. Memory devices (not shown) containing personal information or financial modules allowing digital financial transactions may also be stored in the compartment or chamber 34.

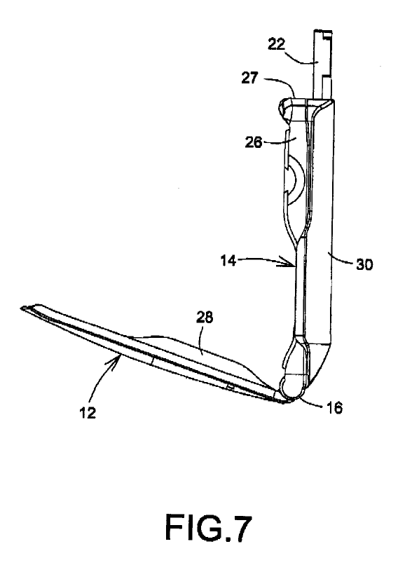

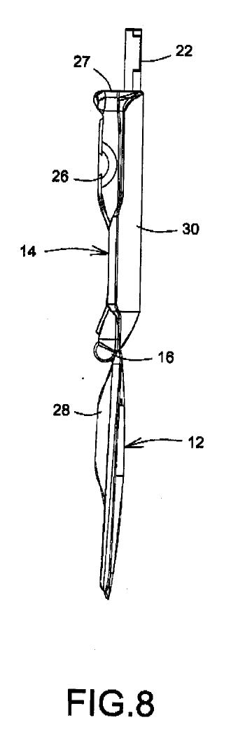

When the case is used by a user, it will be advantageous to open the case to an angle between about 45 and about 90 degrees, preferably about 70 degrees. Such opening allows access to the interior of the case, but prevents Items within the case from falling out. The hinge mechanism 16 typically has a stop (not shown) causing the case to open and be stable at such an angle, as seen in FIG. 7. Typically, the resistance of the stop may be overcome to open the case at 180 degrees to a full flat configuration, seen in FIG. 8.

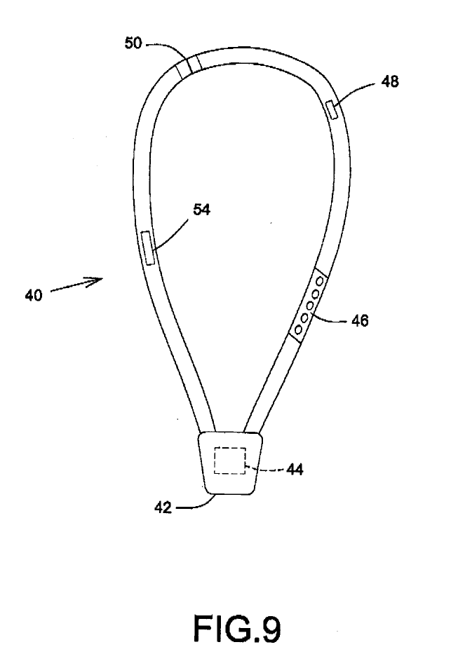

The carrying case may typically include features such as speakers, antennas, a wireless device such as Bluetooth™ and voice recognition in order to enhance communication, entertainment and hands free capability of the case. As seen in FIG. 9, these components may also typically be integrated into an embodiment of an attachment or carrying strap 40, such as a lanyard, belt or shoulder strap. It is possible and known to incorporate electronic components into textiles for the making of clothing or other articles. Such textiles are sold under the name Interactive Wear™.

FIG. 9 depicts the front side of an attachment strap 40. A connector 42, being either a simple mechanical connector when no electronic connection are required, or an electronic connector, such as a 12-pin Ipod™ connector or the like, when for connection to an electronic device 22, typically mates with either a typically female connector (not shown) on the electronic device 22 or with the female electronic connector 43 on the carrying case, seen in FIG. 5a, when an electronic device is not attached. In this manner, the strap 40 may be attached to either an electronic device 22 or the carrying case 10 alone, or both, when the two are attached to one another.

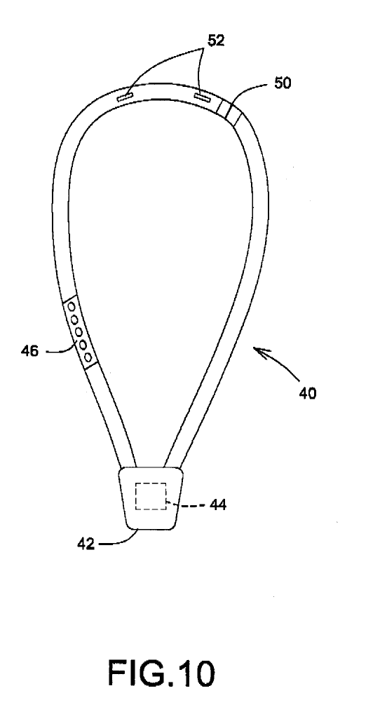

A wireless device, such as a Bluetooth™ module 44, is typically integrated into the strap above the connector 42, as shown by the dotted lines in FIGS. 9 and 10. Typically, controls, preferably in the form of a reversible key pad 46, have buttons suitable for operating a connected electronic device. A microphone 48 is typically placed on the strap so that is will be near the wearer's head when worn. The strap preferably has a quick release strap fastener 50, as is required in many workplaces. In FIG. 10, the back side of the strap is seen, with the reversible key pad still accessible and preferably headphone connectors 52, also positioned so as to be in a convenient position when the strap is worn. Typically, pockets 54 may also be incorporated into the strap to accommodate personal articles and other electronic devices.

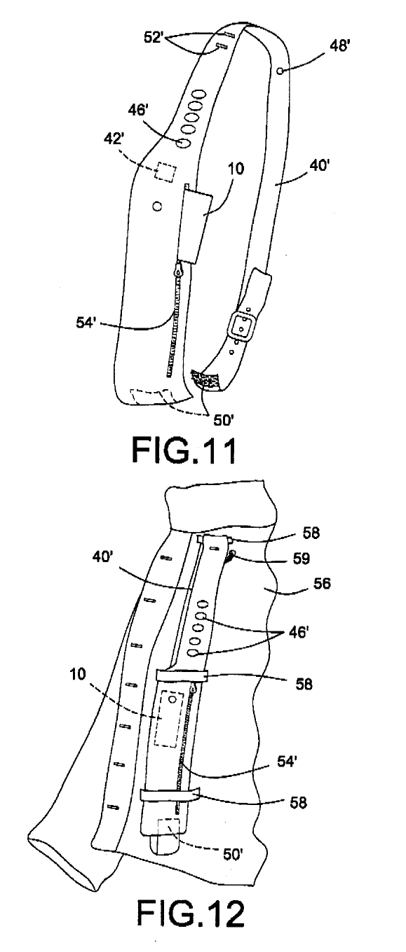

As shown in FIG. 11, another embodiment of a carrying shoulder strap 40′ typically has a wider section with pockets 54′ (preferably on both sides, and closable with typically sealing zippers) large enough to receive, typically in a front pocket, personal instruments such as the carrying case 10 and/or other electronic devices and/or personal cards, along with appropriate electronic connector(s) 42′ (electronic or not) when applicable, and, typically in a back pocket, all electronic components, such as electrical wiring, chemical and/or solar batteries, etc. Having the electronic components in a separate back pocket allows the strap to be easily customizable and up-gradable with ever-changing technologies. The shoulder strap 40′ also 50′ typically includes corresponding key pad controls 46′, microphone 48′ and/or headphone connectors 52′, as well as a quick strap fastener 50′, such as Velcro™ type or the like. To provide certain rigidity to the strap 40, as well as to protect the integration of electronic components during its making, the strap typically includes thermo-welded/binded seam edges.

Furthermore, the carrying strap 40′ could be releasably attached and Integrated into a piece of clothing such as Inside of a jacket 56 or the like via corresponding strap securing means, such as loops 58, snaps or the like, as shown in FIG. 12. When secured to the inside of the jacket 56, the keypad 46′ of the strap 40 could be accessible through the jacket by corresponding key marks printed thereon and respectively in general register therewith. Although not all shown, the carrying Jacket 56 could also be made of textile with incorporated electronic components, and typically include electronic connectors and wires 59 (or alternatively wireless type), as well as corresponding key pad controls (typically located on the sleeve) that can communicate with the carrying strap component(s), microphone and/or headphone connectors.

The carrying case represents maximum functionality and ease of use in a small, easy to use, aesthetically pleasing configuration for protecting both personal information and personal property. While the invention has been described with reference to a preferred embodiment, variation and modification would be apparent to one of ordinary skill in the art without departing from the scope of the invention. The invention encompasses such variations and modifications.

Although the present invention has been described with a certain degree of particularity, it is to be understood that the disclosure has been made by way of example only and that the present invention is not limited to the features of the embodiments described and illustrated herein, but includes all variations and modifications within the scope and spirit of the invention as hereinafter claimed.

1-12. (canceled)

13. A personal carrier, comprising:
a carrying strap (40) including an electronic connector (42) for connecting to either a personal carrying case (10) or a personal electronic device;
controls (46) integrated into the strap (40) and connecting to the connector (42) for operation of the personal carrying case (10) and/or the personal electronic device; and
at least one pocket (54) for receiving the personal carrying case (10) and/or the personal electronic device and having said electronic connector (42) located therein.

14. The carrier of claim 13, wherein the strap (40) is made out of a textile incorporating electronic components or devices and defines channel means extending along the strap (40) for integrating connecting wires of the controls (46) and the connector (42) therealong.

15. The carrier of claim 13, further comprising:
headphone connectors (52) integrated thereinto and connecting to the electronic connector (42).

16. The carrier of claim 13, wherein the at least one pocket (54) includes a first pocket for receiving the personal carrying case (10) and/or the personal electronic device, and a second pocket for receiving electronic components therein, said first and second pockets being adjacent to one another for connection of the personal carrying case (10) and/or the personal electronic device to the electronic components.

17. The carrier of claim 13, wherein the strap (40) has thermo-welded seam edges.

18. The carrier of claim 13, further comprising:
a carrying jacket (56) having strap securing means (58) for attaching the strap (40) thereto, said jacket having electronic components thereon for connection with the personal carrying case (10) and/or the personal electronic device.

19. The carrier of claim 13, wherein the at least one pocket (54) is located in a wider section of the strap (40).

20. The carrier of claim 13, wherein the strap (40) includes at least one strap securing means (58) for releasable attachment thereof to a piece of clothing.

21. The carrier of claim 14, wherein the strap (40) includes at least one strap securing means (58) for releasable attachment thereof to a piece of clothing.

22. The carrier of claim 16, wherein the strap (40) includes at least one strap securing means (58) for releasable attachment thereof to a piece of clothing.

23. The carrier of claim 16, wherein the strap (40) is made out of a textile incorporating electronic components or devices and defines channel means extending along the strap (40) for integrating connecting wires of the controls (46) and the connector (42) therealong.

24. The carrier of claim 19, wherein the strap (40) is made out of a textile incorporating electronic components or devices and defines channel means extending along the strap (40) for integrating connecting wires of the controls (46) and the connector (42) therealong.

25. The carrier of claim 20, wherein the strap (40) is made out of a textile incorporating electronic components or devices and defines channel means extending along the strap (40) for integrating connecting wires of the controls (46) and the connector (42) therealong.
